(19) United States
(12) Patent Application Publication
(10) Pub. No.: US 2023/0180515 A1
(43) Pub. Date: Jun. 8, 2023

(54) DISPLAY DEVICE INCLUDING INORGANIC INSULATING LAYERS

(71) Applicant: SAMSUNG DISPLAY CO., LTD., YONGIN-SI (KR)

(72) Inventors: NARI HEO, Hwaseong-si (KR); HYUN-GUE SONG, Hwaseong-si (KR); HEESEONG JEONG, Suwon-si (KR); SANG MIN HONG, Cheonan-si (KR)

(21) Appl. No.: 18/046,501

(22) Filed: Oct. 13, 2022

(30) Foreign Application Priority Data
Dec. 2, 2021 (KR) 10-2021-0171056

(51) Int. Cl. H01L 51/52; H01L 27/32

(52) U.S. Cl. CPC H01L 51/5253; H01L 27/322; H01L 51/5275; H01L 51/5284; H01L 27/323

(57) ABSTRACT

A display device includes a display panel and a color filter. The display panel includes a light emitting element, an organic capping layer having a first refractive index, and a thin film encapsulation layer. The thin film encapsulation layer includes a first inorganic insulating layer, having a second refractive index, disposed directly on the organic capping layer, a second inorganic insulating layer, having a third refractive index, disposed directly on the first inorganic insulating layer, a third inorganic insulating layer, having a fourth refractive index, disposed directly on the second inorganic insulating layer, an organic layer disposed directly on the third inorganic insulating layer, and a fourth inorganic insulating layer disposed directly on the organic layer. The first and third refractive indices are each greater than the second refractive index, and the second and fourth refractive indices are each smaller than the third refractive index.

This U.S. non-provisional patent application claims priority under 35 U.S.C. § 119 to Korean Patent Application No. 10-2021-0171056, filed on Dec. 2, 2021, the contents of which are hereby incorporated by reference in its entirety.

### TECHNICAL FIELD

The present disclosure relates to a display device and, more specifically, to a display device including a plurality of inorganic insulating layers.

### DISCUSSION OF THE RELATED ART

A display device may be used to display a variety of images through a display panel so as to provide a user with visual information. The display device generally includes a thin film encapsulation layer. The thin film encapsulation layer protects a light emitting element layer from moisture, oxygen, and a foreign substance, e.g., dust particles. The thin film encapsulation layer includes a plurality of organic and inorganic layers.

### SUMMARY

A display device includes a display panel and a color filter. The display panel includes a light emitting element, an organic capping layer disposed on the light emitting element and having a first refractive index, and a thin film encapsulation layer disposed on the organic capping layer. The color filter is disposed on the display panel and corresponds to the light emitting element. The thin film encapsulation layer includes a first inorganic insulating layer disposed directly on the organic capping layer and having a second refractive index, a second inorganic insulating layer disposed directly on the first inorganic insulating layer and having a third refractive index, a third inorganic insulating layer disposed directly on the second inorganic insulating layer and having a fourth refractive index, an organic layer disposed directly on the third inorganic insulating layer, and a fourth inorganic insulating layer disposed directly on the organic layer. The first refractive index and the third refractive index are each greater than the second refractive index. The second refractive index and the fourth refractive index are each smaller than the third refractive index.

A difference between the first refractive index and the second refractive index may be greater than a difference between the second refractive index and the third refractive index. A difference between the second refractive index and the third refractive index may be greater than a difference between the third refractive index and the fourth refractive index.

The organic capping layer may have a thickness that is greater than or equal to about 450 angstroms and less than or equal to about 650 angstroms. The first refractive index may be greater than or equal to about 1.8 and less than or equal to about 2.1.

The first inorganic insulating layer may have a thickness that is greater than or equal to about 1100 angstroms and less than or equal to about 1600 angstroms. The second refractive index may be greater than or equal to about 1.4 and less than or equal to about 1.7.

The second inorganic insulating layer may have a thickness that is greater than or equal to about 8000 angstroms and less than or equal to about 11000 angstroms. The third refractive index may be greater than or equal to about 1.75 and less than or equal to about 1.9.

The third inorganic insulating layer may have a thickness that is greater than or equal to about 500 angstroms and less than or equal to about 800 angstroms. The fourth refractive index may be greater than or equal to about 1.6 and less than or equal to about 1.7.

The first inorganic insulating layer, the second inorganic insulating layer, and the third inorganic insulating layer may each include SiOxNy. The first inorganic insulating layer may have an oxygen composition ratio (x) of about 0.77 and a nitrogen composition ratio (y) of about 0.42. The second inorganic insulating layer may have an oxygen composition ratio (x) of about 0.27 and a nitrogen composition ratio (y) of about 0.65. The third inorganic insulating layer may have an oxygen composition ratio (x) of about 0.68 and a nitrogen composition ratio (y) of about 0.47.

As used herein, the phrase “oxygen composition ratio” refers to a ratio of moles of oxygen within a compound to the total moles of the compound (or to some other element within the compound) and similarly, the phrase “nitrogen composition ratio” refers to a moles of nitrogen within a compound to the total moles of the compound (or to some other element within the compound).

The first inorganic insulating layer, the second inorganic insulating layer, and the third inorganic insulating layer may each include SiOxNy. The first inorganic insulating layer may have an oxygen composition ratio (x) of about 1.2 and a nitrogen composition ratio (y) of about 0.25. The second inorganic insulating layer may have an oxygen composition ratio (x) of about 0 and a nitrogen composition ratio (y) of about 0.72. The third inorganic insulating layer may have an oxygen composition ratio (x) that is greater than about 0.27 and smaller than about 0.68 and a nitrogen composition ratio (y) that is greater than about 0.47 and smaller than about 0.65.

The first inorganic insulating layer, the second inorganic insulating layer, and the third inorganic insulating layer may each include SiOxNy. The first inorganic insulating layer may have an oxygen composition ratio (x) of about 1.2 and a nitrogen composition ratio (y) of about 0.25. The second inorganic insulating layer may have an oxygen composition ratio (x) of about 0.27 and a nitrogen composition ratio (y) of about 0.65. The third inorganic insulating layer may have an oxygen composition ratio (x) of about 0.68 and a nitrogen composition ratio (y) of about 0.47.

The first inorganic insulating layer, the second inorganic insulating layer, and the third inorganic insulating layer may each include SiOxNy, an oxygen composition ratio (x) may be greater than or equal to about 0 and less than or equal to about 1.2, and a nitrogen composition ratio (y) may be greater than or equal to about 0.25 and less than or equal to about 0.72.

The display device may further include a black matrix disposed adjacent to the color filter and an overcoat layer covering both the color filter and the black matrix.

The display device may further include an input sensor layer disposed between the thin film encapsulation layer and the color filter.

A display device includes a display panel including a light emitting element, an organic capping layer disposed on the light emitting element and having a first refractive index, a thin film encapsulation layer disposed on the organic capping layer, an input sensor layer disposed directly on the display panel, and an optical member disposed on the input sensor layer. The thin film encapsulation layer includes a first inorganic insulating layer disposed directly on the organic capping layer and having a second refractive index, a second inorganic insulating layer disposed directly on the first inorganic insulating layer and having a third refractive index, a third inorganic insulating layer disposed directly on the second inorganic insulating layer and having a fourth refractive index, an organic layer disposed directly on the third inorganic insulating layer, and a fourth inorganic insulating layer disposed directly on the organic layer. The first refractive index and the third refractive index are each greater than the second refractive index. The second refractive index and the fourth refractive index are each smaller than the third refractive index. A difference between the first refractive index and the second refractive index is greater than a difference between the second refractive index and the third refractive index. The difference between the second refractive index and the third refractive index is greater than a difference between the third refractive index and the fourth refractive index.

The difference between the first refractive index and the second refractive index may be greater than or equal to about 0.45 and less than or equal to about 0.55. The difference between the second refractive index and the third refractive index may be greater than or equal to about 0.2 and less than or equal to about 0.42. The difference between the third refractive index and the fourth refractive index may be greater than or equal to about 0.1 and less than or equal to about 0.2.

The optical member may include a polarizing film or a color filter.

The input sensor layer may include a base insulating layer disposed on the display panel, a first conductive layer disposed on the base insulating layer, a sensing insulating layer disposed on the first conductive layer, a second conductive layer disposed on the sensing insulating layer, and a cover layer disposed on the second conductive layer.

The organic capping layer may have a thickness that is greater than or equal to about 450 angstroms and less than or equal to about 650 angstroms. The first refractive index may be greater than or equal to about 1.8 and less than or equal to about 2.1.

The first inorganic insulating layer may have a thickness that is greater than or equal to about 1100 angstroms and less than or equal to about 1600 angstroms. The second refractive index may be greater than or equal to about 1.4 and less than or equal to about 1.7.

The second inorganic insulating layer may have a thickness that is greater than or equal to about 8000 angstroms and less than or equal to about 11000 angstroms. The third refractive index may be greater than or equal to about 1.75 and less than or equal to about 1.9.

The third inorganic insulating layer may have a thickness that is greater than or equal to about 500 angstroms and less than or equal to about 800 angstroms. The fourth refractive index may be greater than or equal about 1.6 and less than or equal to about 1.7.

### BRIEF DESCRIPTION OF THE DRAWINGS

The above and other aspects of the present disclosure will become readily apparent by reference to the following detailed description when considered in conjunction with the accompanying drawings, wherein:

FIG. 1 is a perspective view of a display device according to an embodiment of the present disclosure;

FIG. 2A is a cross-sectional view of a display device according to an embodiment of the present disclosure;

FIG. 2B is a cross-sectional view of a portion of a display device according to an embodiment of the present disclosure;

FIG. 3A is a cross-sectional view of a display device according to an embodiment of the present disclosure;

FIG. 3B is a cross-sectional view of a display panel according to an embodiment of the present disclosure;

FIG. 4A is a cross-sectional view of some component of a display panel according to an embodiment of the present disclosure;

FIG. 4B is a table showing a composition ratio of an inorganic layer of FIG. 4A;

FIG. 5A is a cross-sectional view of some component of a display panel according to an embodiment of the present disclosure;

FIG. 5B is a table showing a composition ratio of an inorganic layer of FIG. 5A;

FIG. 6A is a cross-sectional view of some component of a display panel according to an embodiment of the present disclosure;

FIG. 6B is a table showing a composition ratio of an inorganic layer of FIG. 6A;

FIG. 7 is a graph showing spectral results of a green light passing through an inorganic layer according to a comparative example and an inorganic layer according to an embodiment of the present disclosure;

FIG. 8A is a graph showing spectral results of a green light before and after passing through a color filter of a display device including two inorganic insulating layers;

FIG. 8B is a graph showing spectral results of a green light before and after passing through a color filter of a display device including three inorganic insulating layers according to an embodiment of the present disclosure;

FIG. 9A is a graph showing spectral results of a green light before and after passing through a polarizing film of a display device including two inorganic insulating layers; and

FIG. 9B is a graph showing spectral results of a green light before and after passing through a polarizing film of a display device including three inorganic insulating layers according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals may refer to like elements throughout the drawings and the specification. In the drawings, the thickness, ratio, and dimension of components are intended to represent at least one embodiment of the present disclosure. As used herein, the term “and/or” may include any and all combinations of one or more of the associated listed items.

It will be understood that, although the terms first, second, etc. may be used herein to describe various elements, these elements should not necessarily be limited by these terms. These terms may be used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures.

It will be further understood that the terms “comprises,” “comprising,” “includes,” and/or “including”, when used in this specification, specify the presence of stated features, integers, steps, operations, elements, and/or components, but do not necessarily preclude the presence or addition of one or more other features, integers, steps, operations, elements, components, and/or groups thereof.

The term “part” or “unit” as used herein may mean a software component or a hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, segments of program code, drivers, firmware, micro codes, circuits, data, a database, data structures, tables, arrays, or variables.

Hereinafter, embodiments of the present disclosure will be described with reference to accompanying drawings.

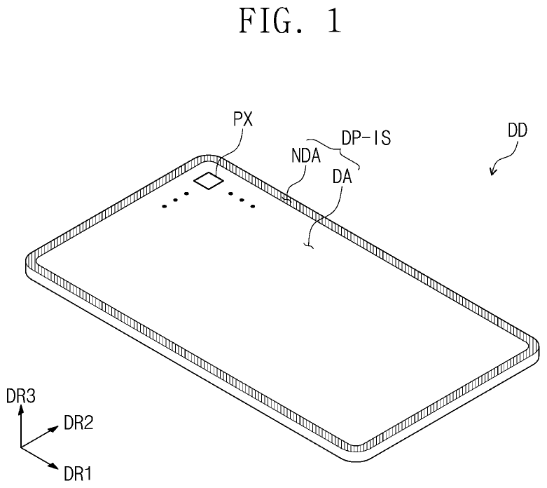

FIG. 1 is a perspective view of a display device DD according to an embodiment of the present disclosure.

Referring to FIG. 1, the display device DD may display an image through a display surface DP-IS. The display surface DP-IS may be substantially parallel to a plane defined by a first direction DR1 and a second direction DR2. An upper surface of a member disposed at an uppermost position of the display device DD may be defined as the display surface DP-IS.

A third direction DR3 may indicate a normal line direction of the display surface DP-IS, i.e., a thickness direction of the display device DD. Front (or upper) and rear (or lower) surfaces of each layer or each unit are distinguished from each other by the third direction DR3.

The display device DD may include a display area DA and a non-display area NDA. Pixels PX may be arranged in the display area DA, and the pixels PX might not be arranged in the non-display area NDA. The non-display area NDA may be defined along an edge of the display surface DP-IS. The non-display area NDA may at least partially surround the display area DA. According to an embodiment, the non-display area NDA may be omitted or may be defined adjacent to only one side of the display area DA. FIG. 1 shows a flat display device DD as a representative example, however, the display device DD may have a curved shape.

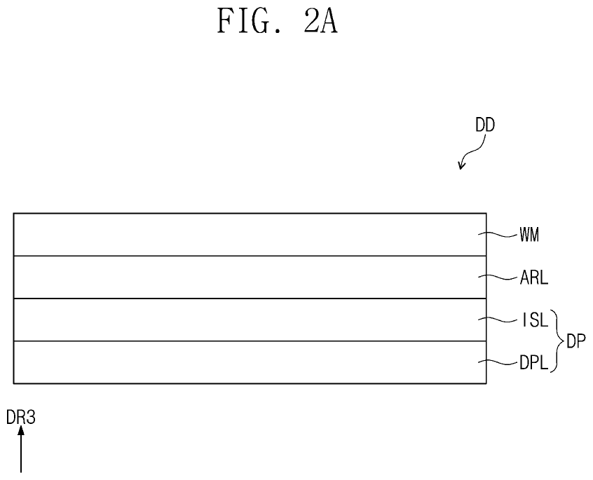

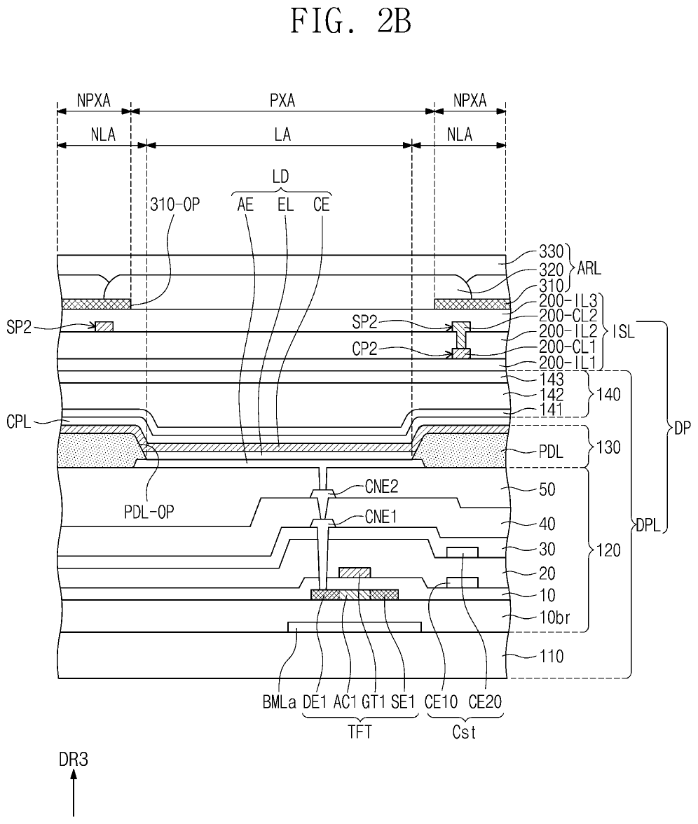

FIG. 2A is a cross-sectional view of the display device DD according to an embodiment of the present disclosure.

Referring to FIG. 2A, the display device DD may include a display panel DP, an anti-reflective layer ARL, and a window WM. The display panel DP may include a display layer DPL and an input sensor layer ISL.

The display layer DPL may be a light emitting type display layer. For example, the display layer DPL may be an organic light emitting diode (OLED) display layer, an inorganic light emitting display layer, an organic-inorganic light emitting display layer, a micro-LED display layer, or a nano-LED display layer.

The input sensor layer ISL may be disposed on the display layer DPL. The input sensor layer ISL may sense an external input applied thereto. For example, the external input may be a user's touch. The user's touch may be sensed by a variety of factors, such as by light, heat, or pressure. The user's touch may be a touch of a finger or a touch of an active or passive stylus/pen.

The input sensor layer ISL may be formed on the display layer DPL through successive processes. In this case, the input sensor layer ISL may be disposed directly on the display layer DPL. In the present disclosure, the expression “a component A is disposed directly on a component B” means that no intervening elements are present between the component A and the component B. For example, an adhesive member might not be disposed between the input sensor layer ISL and the display layer DPL.

The anti-reflective layer ARL may be disposed on the input sensor layer ISL. The anti-reflective layer ARL may reduce a reflectance of an external light. The anti-reflective layer ARL may be disposed directly on the input sensor layer ISL through successive processes.

The anti-reflective layer ARL may include a light blocking pattern overlapping a reflective structure disposed under the anti-reflective layer ARL. The anti-reflective layer ARL may further include a color filter 320 (refer to FIG. 2B) overlapping a light emitting area. The color filter 320 may include a first color filter, a second color filter, and a third color filter, which respectively correspond to a first color pixel, a second color pixel, and a third color pixel. Detailed descriptions of the anti-reflective layer ARL will be described later.

The window WM may be disposed on the anti-reflective layer ARL. The window WM and the anti-reflective layer ARL may be coupled to each other by an adhesive layer. The adhesive layer may be a pressure sensitive adhesive (PSA) film or an optically clear adhesive (OCA).

The window WM may include at least one base layer. The base layer may be a glass substrate or a synthetic resin film. The window WM may have a single layer or a multi-layer structure. The window WM may include a thin film glass substrate and a synthetic resin film disposed on the thin film glass substrate. The thin film glass substrate and the synthetic resin film may be coupled to each other by an adhesive layer, and the adhesive layer and the synthetic resin film may be separated from the thin film glass substrate to be replaced.

According to an embodiment, the adhesive layer may be omitted, and the window WM may be disposed directly on the anti-reflective layer ARL. An organic material, an inorganic material, or a ceramic material may be coated on the anti-reflective layer ARL.

FIG. 2B is a cross-sectional view of a portion of the display device DD (refer to FIG. 1) according to an embodiment of the present disclosure. FIG. 2B shows a cross-section of the display layer DPL, the input sensor layer ISL, and the anti-reflective layer ARL of the display device DD.

FIG. 2B shows a cross-section corresponding to one light emitting area LA and a non-light-emitting area NLA around the one light emitting area LA. FIG. 2B shows only one light emitting area LA, however, the light emitting area LA may be provided in plural. FIG. 2B shows a light emitting element LD and a transistor TFT connected to the light emitting element LD. The transistor TFT may be one of a plurality of transistors included in a driving circuit of the pixels PX (refer to FIG. 1). In the present embodiment, the transistor TFT will be described as a silicon transistor, however, according to an embodiment, the transistor TFT may be a metal oxide transistor.

Referring to FIG. 2B, the display panel DP may include the display layer DPL and the input sensor layer ISL. The display layer DPL may include a base layer 110, a circuit layer 120, a light emitting element layer 130, an organic capping layer CPL, and a thin film encapsulation layer 140.

The base layer 110 may provide a base surface on which the circuit layer 120 is disposed. The base layer 110 may be a rigid substrate or a flexible substrate that is bendable, foldable, or rollable. The base layer 110 may be a glass substrate, a metal substrate, or a polymer substrate, however, the present disclosure is not necessarily limited thereto or thereby. According to an embodiment, the base layer 110 may be an inorganic layer, an organic layer, or a composite material layer.

The base layer 110 may have a single layer structure or a multi-layer structure. For example, the base layer 110 may include a first synthetic resin layer, an inorganic layer having a single-layer or multi-layer structure, and a second synthetic resin layer disposed on the inorganic layer and having a single-layer or multi-layer structure. Each of the first and second synthetic resin layers may include a polyimide-based resin, however, the present disclosure is not necessarily limited thereto or thereby.

The circuit layer 120 may be disposed on the base layer 110. The circuit layer 120 may include an insulating layer, a semiconductor pattern, a conductive pattern, a signal line, and a driving circuit of the pixels PX. The circuit layer 120 may include a buffer layer 10br and first, second, third, fourth, and fifth insulating layers 10, 20, 30, 40, and 50.

The buffer layer 10br may be disposed on the base layer 110. The buffer layer 10br may prevent metal atoms or impurities from being diffused to the semiconductor pattern disposed thereon from the base layer 110. The semiconductor pattern may include an active area AC1 of the transistor TFT.

A rear surface metal layer BMLa may be disposed under the transistor TFT, and the rear surface metal layer BMLa may prevent the external light from reaching the transistor TFT. The rear surface metal layer BMLa may be disposed between the base layer 110 and the buffer layer 10br. According to an embodiment, a barrier layer, for example, an inorganic layer, may be further disposed between the rear surface metal layer BMLa and the buffer layer 10br. The rear surface metal layer BMLa may be an electrode or a conductive line and may receive a constant voltage or signal from the electrode or the line.

The semiconductor pattern may be disposed on the buffer layer 10br. The semiconductor pattern may include a silicon semiconductor. As an example, the silicon semiconductor may include amorphous silicon or polycrystalline silicon. For example, the semiconductor pattern may include low temperature polycrystalline silicon.

The semiconductor pattern may include a first region having a relatively high conductivity and a second region having a relatively low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or a region doped at a concentration that is lower than that of the first region.

The first region may have a conductivity that is greater than that of the second region and may substantially serve as an electrode or a signal line. The second region may substantially correspond to an active area (or a channel) of the transistor. For example, a portion of the semiconductor pattern may be the active area of the transistor, another portion of the semiconductor pattern may be a source or a drain of the transistor, and another portion of the semiconductor pattern may be a connection electrode or a connection signal line.

The transistor TFT may include a source area SE1 (or a source), the active area AC1 (or a channel), a drain area DE1 (or a drain), and a gate GT1. The source area SE1, the active area AC1, and the drain area DE1 of the transistor TFT may be formed from the semiconductor pattern. The source area SE1 and the drain area DE1 may extend in opposite directions to each other from the active area AC1 in a cross-sectional view.

The first insulating layer 10 may be disposed on the buffer layer 10br. The first insulating layer 10 may commonly overlap the pixels and may cover the semiconductor pattern. The first insulating layer 10 may include an inorganic layer and/or an organic layer and may have a single-layer or multi-layer structure. The inorganic layer may include aluminum oxide, titanium oxide, silicon oxide, silicon nitride, silicon oxynitride, zirconium oxide, and/or hafnium oxide. In the present embodiment, the first insulating layer 10 may have a single-layer structure of a silicon oxide layer. Not only the first insulating layer 10, but also an insulating layer of the circuit layer 120 described later may be an inorganic layer and/or an organic layer and may have a single-layer or multi-layer structure. The inorganic layer may include at least one of the above-mentioned materials, however, the present disclosure is not necessarily limited thereto or thereby.

The gate GT1 of the transistor TFT may be disposed on the first insulating layer 10. The gate GT1 may be a portion of a metal pattern. The gate GT1 may overlap the active area AC1. The gate GT1 may be used as a mask in a process of doping the semiconductor pattern. The gate GT1 may include titanium (Ti), silver (Ag), an alloy including silver (Ag), molybdenum (Mo), an alloy including molybdenum (Mo), aluminum (Al), an alloy including aluminum (Al), aluminum nitride (AlN), tungsten (W), tungsten nitride (WN), copper (Cu), indium tin oxide (ITO), indium zinc oxide (IZO), or the like, however, the present disclosure is not necessarily limited thereto or thereby.

A first capacitor electrode CE10 of a storage capacitor Cst may be disposed on the first insulating layer 10. The second insulating layer 20 may be disposed on the first insulating layer 10 and may cover the gate GT1 and the first capacitor electrode CE10 of the storage capacitor Cst. A second capacitor electrode CE20 of the storage capacitor Cst may be disposed on the second insulating layer 20. The third insulating layer 30 may be disposed on the second insulating layer 20 and may cover the second capacitor electrode CE20 of the storage capacitor Cst.

A first connection electrode CNE1 may be disposed on the third insulating layer 30. The first connection electrode CNE1 may be connected to the drain area DE1 of the transistor TFT via a contact hole defined through the first, second, and third insulating layers 10, 20, and 30.

The fourth insulating layer 40 may be disposed on the third insulating layer 30. A second connection electrode CNE2 may be disposed on the fourth insulating layer 40. The second connection electrode CNE2 may be connected to the first connection electrode CNE1 via a contact hole defined through the fourth insulating layer 40. The fifth insulating layer 50 may be disposed on the fourth insulating layer 40 and may cover the second connection electrode CNE2. The stack structure of the first insulating layer 10 to the fifth insulating layer 50 is described an example, and additional conductive layer and insulating layer may be disposed in addition to the first insulating layer 10 to the fifth insulating layer 50.

Each of the fourth insulating layer 40 and the fifth insulating layer 50 may include an organic layer. For example, the organic layer may include a general-purpose polymer such as benzocyclobutene (BCB), polyimide, hexamethyldisiloxane (HMDSO), polymethylmethacrylate (PMMA), or polystyrene (PS), a polymer derivative having a phenolic group, an acrylic-based polymer, an imide-based polymer, an aryl ether-based polymer, an amide-based polymer, a fluorine-based polymer, a p-xylene-based polymer, a vinyl alcohol-based polymer, or blends thereof.

The light emitting element layer 130 may be disposed on the circuit layer 120. The light emitting element layer 130 may include the light emitting element LD and a pixel definition layer PDL. The light emitting element LD may be an organic light emitting element, an inorganic light emitting element, an organic-inorganic light emitting element, a quantum dot light emitting element, a micro-LED light emitting element, or a nano-LED light emitting element. However, the light emitting element LD is not necessarily limited thereto or thereby as long as the light emitting element LD may emit a light in response to electrical signals or may control an amount of the light.

The light emitting element LD may include a first electrode AE (or a pixel electrode), a light emitting layer EL, and a second electrode CE (or a common electrode). The first electrode AE may be disposed on the fifth insulating layer 50. The first electrode AE may be a semi-transmissive electrode, a transmissive electrode, or a reflective electrode. According to an embodiment, the first electrode AE may include a reflective layer formed of Ag, Mg, Al, Pt, Pd, Au, Ni, Nd, Jr, Cr, or compounds thereof and a transparent or semi-transparent electrode layer formed on the reflective layer. The transparent or semi-transparent electrode layer may include indium tin oxide (ITO), indium zinc oxide (IZO), indium gallium zinc oxide (IGZO), zinc oxide (ZnO), indium oxide (In₂O₃), and/or aluminum-doped zinc oxide (AZO). For example, the first electrode AE may have a stack structure of ITO/Ag/ITO.

The pixel definition layer PDL may be disposed on the fifth insulating layer 50. The pixel definition layer PDL may have a light absorbing property. For example, the pixel definition layer PDL may have a black color. The pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light blocking pattern having a light blocking property.

The pixel definition layer PDL may cover a portion of the first electrode AE. As an example, an opening PDL-OP may be defined through the pixel definition layer PDL to expose the portion of the first electrode AE. The opening PDL-OP of the pixel definition layer PDL may define the light emitting area LA.

The pixel definition layer PDL may increase a distance between an edge of the first electrode AE and the second electrode CE. Accordingly, an occurrence of electrical arcing in the edge of the first electrode AE may be prevented by the pixel definition layer PDL.

A hole control layer may be disposed between the first electrode AE and the light emitting layer EL. The hole control layer may include a hole transport layer and may further include a hole injection layer. An electron control layer may be disposed between the light emitting layer EL and the second electrode CE. The electron control layer may include an electron transport layer and may further include an electron injection layer.

The organic capping layer CPL may be disposed on the light emitting element LD and may cover the second electrode CE of the light emitting element LD. The organic capping layer CPL may include an organic material. The organic capping layer CPL may have a single-layer or multi-layer structure. The organic capping layer CPL may protect an organic light emitting layer disposed thereunder from moisture or contaminants from the outside, and thus, a lifespan of the light emitting element LD may be increased.

The thin film encapsulation layer 140 may be disposed on the organic capping layer CPL. The thin film encapsulation layer 140 may protect the light emitting element layer 130 from moisture, oxygen, and a foreign substance such as dust particles. The thin film encapsulation layer 140 may include an inorganic layer 141, an organic layer 142, and a fourth inorganic insulating layer 143, which are sequentially stacked, however, layers forming the thin film encapsulation layer 140 is not necessarily limited thereto or thereby.

The inorganic layers 141 and 143 may protect the light emitting element layer 130 from moisture and oxygen, and the organic layer 142 may protect the light emitting element layer 130 from the foreign substance such as dust particles. The inorganic layers 141 and 143 may include a silicon nitride layer, a silicon oxynitride layer, a silicon oxide layer, a titanium oxide layer, or an aluminum oxide layer. The organic layer 142 may include an acrylic-based organic layer, however, the present disclosure is not necessarily limited thereto or thereby.

The input sensor layer ISL may be disposed on the display layer DPL. The input sensor layer ISL may be disposed between the thin film encapsulation layer 140 and the color filter 320 and between the thin film encapsulation layer 140 and a light blocking pattern 310 (or a black matrix). The input sensor layer ISL may be referred to as a sensor layer, an input sensing layer, or an input sensing panel. The input sensor layer ISL may include a base insulating layer 200-IL1, a first conductive layer 200-CL1, a sensing insulating layer 200-IL2, a second conductive layer 200-CL2, and a cover layer 200-IL3. The base insulating layer 200-IL1 may be disposed directly on the display layer DPL. The base insulating layer 200-IL1 may be an inorganic layer including silicon nitride, silicon oxynitride, and/or silicon oxide. According to an embodiment, the base insulating layer 200-IL1 may be an organic layer including an epoxy resin, an acrylic resin, or an imide-based resin. The base insulating layer 200-IL1 may have a single-layer structure or a multi-layer structure of layers stacked in the third direction DR3.

Each of the first conductive layer 200-CL1 and the second conductive layer 200-CL2 may have a single-layer structure or a multi-layer structure of layers stacked in the third direction DR3. Each of the first conductive layer 200-CL1 and the second conductive layer 200-CL2 may include a sensing pattern, which has a mesh structure, or a bridge pattern.

The conductive layer having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (IZTO), or the like. In addition, the transparent conductive layer may include conductive polymer such as PEDOT, metal nanowire, graphene, or the like.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensing insulating layer 200-IL2 may be disposed between the first conductive layer 200-CL1 and the second conductive layer 200-CL2. The cover layer 200-IL3 may be disposed on the sensing insulating layer 200-IL2 and may cover the second conductive layer 200-CL2. The cover layer 200-IL3 may reduce or remove a probability of damage to the second conductive layer 200-CL2 in the subsequent process. According to an embodiment, the input sensor layer ISL might not include the cover layer 200-IL3.

The sensing insulating layer 200-IL2 and the cover layer 200-IL3 may each include an inorganic layer. The inorganic layer may include aluminum oxide, titanium oxide, silicon oxide, silicon nitride, silicon oxynitride, zirconium oxide, and/or hafnium oxide.

According to an embodiment, the sensing insulating layer 200-IL2 and the cover layer 200-IL3 may include an organic layer. The organic layer may include an epoxy-based resin, a urethane-based resin, a cellulose-based resin, a siloxane-based resin, a polyimide-based resin, a polyamide-based resin, and/or a perylene-based resin.

The anti-reflective layer ARL may be disposed on the input sensor layer ISL. The anti-reflective layer ARL may include the light blocking pattern 310, the color filter 320, and a planarization layer 330 (or an overcoat layer).

A material for the light blocking pattern 310 is not necessarily limited to what has been described herein as along as the material may absorb light. The light blocking pattern 310 may have a black color. The light blocking pattern 310 may include a black coloring agent. The black coloring agent may include a black dye or a black pigment. The black coloring agent may include a metal material, such as carbon black, chromium, or an oxide thereof.

The light blocking pattern 310 may overlap the bridge pattern CP2 and the sensing pattern SP2, in a plan view. The light blocking pattern 310 may be disposed adjacent to the color filter 320.

The light blocking pattern 310 may prevent the external light from being reflected by the first conductive layer 200-CL1 and the second conductive layer 200-CL2. An opening 310-OP may be defined through the light blocking pattern 310. The opening 310-OP of the light blocking pattern 310 may overlap the first electrode AE and may have a size that is greater than that of the opening PDL-OP of the pixel definition layer PDL. The opening 310-OP of the light blocking pattern 310 may define a pixel area PXA. The pixel area PXA may correspond to an area from which the light generated by the light emitting element LD exits to the outside. As the size of the pixel area PXA increases, a luminance of the image may increase.

The color filter 320 may overlap at least the pixel area PXA. The color filter 320 may further overlap a non-pixel area NPXA. A portion of the color filter 320 may be disposed on the light blocking pattern 310. The color filter 320 may transmit the light generated by the light emitting element LD and may block a portion of the external light in at least some wavelength bands. Accordingly, the color filter 320 may reduce the reflection of the external light, which is caused by the first electrode AE or the second electrode CE.

The planarization layer 330 may cover the light blocking pattern 310 and the color filter 320. The planarization layer 330 may include an organic material and may provide a flat (e.g., planar) upper surface thereon.

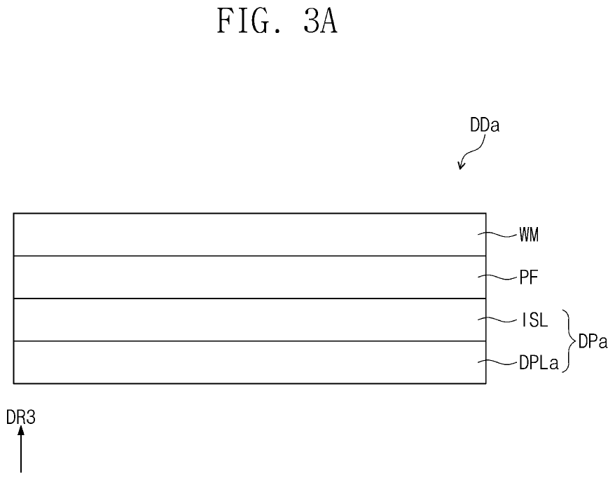

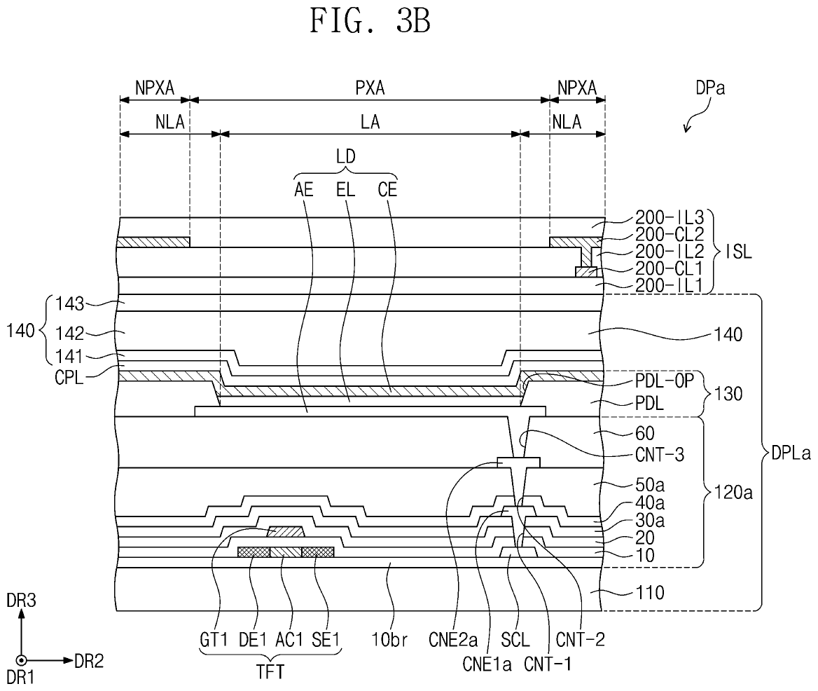

FIG. 3A is a cross-sectional view of a display device DDa according to an embodiment of the present disclosure. In FIG. 3A, the same reference numerals may denote the same elements in FIG. 2A, and thus, to the extent that a detailed descriptions of an element has been omitted, it may be assumed that the element is at least similar to a corresponding element that has been described elsewhere within the present disclosure.

Referring to FIG. 3A, the display device DDa may include a display panel DPa, an optical member PF, and a window WM. The display panel DPa may include a display layer DPLa and an input sensor layer ISL disposed on the display layer DPLa.

According to an embodiment, at least some components of the above-mentioned components may be omitted or other components may be added to the display device DDa. An adhesive layer may be disposed between the components as needed. The adhesive layer may be an optically clear adhesive (OCA) or a pressure sensitive adhesive (PSA) film, however, it is not necessarily limited thereto or thereby. Adhesive layers described hereinafter may include the same material as the above material, e.g., a conventional adhesive.

The display panel DPa may include the display layer DPLa and the sensor layer ISL disposed on the display layer DPLa. The display layer DPLa may have a configuration that substantially generates the image. The display layer DPLa may be a light emitting type display layer. For example, the display layer DPLa may be an organic light emitting display layer, an inorganic light emitting display layer, an organic-inorganic light emitting display layer, a quantum dot display layer, a micro-LED display layer, or a nano-LED display layer.

The optical member PF may be disposed on the input sensor layer ISL. The optical member PF may reduce a reflectance with respect to a light incident thereto from the outside (e.g., ambient light). The optical member PF may include a retarder and/or a polarizer. The optical film PF may include at least a polarizing film. In this case, the optical film PF may be attached to the display panel DPa by the adhesive layer.

FIG. 3B is a cross-sectional view of the display panel DPa according to an embodiment of the present disclosure. In FIG. 3B, the same reference numerals may denote the same elements in FIG. 2B, and thus, to the extent that a detailed descriptions of an element has been omitted, it may be assumed that the element is at least similar to a corresponding element that has been described elsewhere within the present disclosure.

Referring to FIG. 3B, the display panel DPa may include the display layer DPLa and the input sensor layer ISL. The display layer DPLa may include a base layer 110, a circuit layer 120a, a light emitting element layer 130, an organic capping layer CPL, and a thin film encapsulation layer 140.

The circuit layer 120a may be disposed on the base layer 110. The circuit layer 120a may include an insulating layer, a semiconductor pattern, a conductive pattern, a signal line, and a driving circuit for a pixel. The circuit layer 120a may include a buffer layer 10br and first, second, third, fourth, and fifth insulating layers 10, 20, 30a, 40a, and 50a.

The third insulating layer 30a may be disposed on the second insulating layer 20. The third insulating layer 30a may have a single-layer or multi-layer structure. As an example, the third insulating layer 30a may have a multi-layer structure of a silicon oxide layer and a silicon nitride layer.

A first connection electrode CNE1a may be disposed on the third insulating layer 30a. The first connection electrode CNE1a may be connected to a connection signal line SCL via a contact hole CNT-1 defined through the first, second, and third insulating layers 10, 20, and 30a.

The fourth insulating layer 40a may be disposed on the third insulating layer 30a. The fourth insulating layer 40a may have a single-layer structure of a silicon oxide layer. The fifth insulating layer 50a may be disposed on the fourth insulating layer 40a. The fifth insulating layer 50a may be an organic layer.

A second connection electrode CNE2a may be disposed on the fifth insulating layer 50a. The second connection electrode CNE2a may be connected to the first connection electrode CNE1a via a contact hole CNT-2 defined through the fourth insulating layer 40a and the fifth insulating layer 50a.

A sixth insulating layer 60 may be disposed on the fifth insulating layer 50a and may cover the second connection electrode CNE2a. The sixth insulating layer 60 may be an organic layer.

FIG. 4A is a cross-sectional view of some component of the display panel DP according to an embodiment of the present disclosure, and FIG. 4B is a table showing a composition ratio of the inorganic layer 141 of FIG. 4A.

Referring to FIG. 4A, the inorganic layer 141, which is adjacent to the organic capping layer CPL, between the inorganic layers 141 and 143 included the thin film encapsulation layer 140 may include a plurality of inorganic insulating layers IIL1 IIL2, and IIL3. The inorganic insulating layers IIL1 IIL2, and IIL3 may include a first inorganic insulating layer IIL1a second inorganic insulating layer IIL2, and a third inorganic insulating layer IIL3.

The organic capping layer CPL may be a high refractive index layer. The organic capping layer CPL may have a first refractive index n1, and the first refractive index n1 may be greater than or equal to about 1.8 and less than or equal to about 2.1. In FIG. 4A, the first refractive index n1 of the organic capping layer CPL may be about 2.0. The organic capping layer CPL may have a thickness THC that is greater than or equal to about 450 angstroms (Å) and less than or equal to about 650 angstroms (Å).

As used herein, the term “about” may mean within a particular range from the value given, such as within 10%, within 5%, within 2%, within 1%, or some other range.

The first inorganic insulating layer IIL1 may be disposed on the organic capping layer CPL. The first inorganic insulating layer IIL1 may have a second refractive index n2, and the second refractive index n2 may be greater than or equal to about 1.4 and less than or equal to about 1.7. In FIG. 4A, the second refractive index n2 of the first inorganic insulating layer IIL1 may be about 1.57. The first inorganic insulating layer IIL1 may have a thickness TH1 that is greater than or equal to about 1100 angstroms and less than or equal to about 1600 angstroms.

The second inorganic insulating layer IIL2 may be disposed directly on the first inorganic insulating layer IIL1. The second inorganic insulating layer IIL2 may have a third refractive index n3, and the third refractive index n3 may be greater than or equal to about 1.75 and less than or equal to about 1.9. In FIG. 4A, the third refractive index n3 of the second inorganic insulating layer IIL2 may be about 1.77. The second inorganic insulating layer IIL2 may have a thickness TH2 that is greater than or equal to about 8000 angstroms and less than or equal to about 11000 angstroms.

The third inorganic insulating layer IIL3 may be disposed directly on the second inorganic insulating layer IIL2. The third inorganic insulating layer IIL3 may have a fourth refractive index n4, and the fourth refractive index n4 may be greater than or equal to about 1.6 and less than or equal to about 1.7. In FIG. 4A, the fourth refractive index n4 of the third inorganic insulating layer IIL3 may be about 1.62. The third inorganic insulating layer IIL3 may have a thickness TH3 that is greater than or equal to about 500 angstroms and less than or equal to about 800 angstroms.

The organic layer 142 may be disposed directly on the third inorganic insulating layer IIL3. The organic layer 142 may have a thickness of about 8.8 μm. The fourth inorganic insulating layer 143 may be disposed directly on the organic layer 142. The fourth inorganic insulating layer 143 may have a refractive index of about 1.89 and may have a thickness of about 5000 angstroms.

The first refractive index n1 and the third refractive index n3 may be greater than the second refractive index n2, and the second refractive index n2 and the fourth refractive index n4 may be smaller than the third refractive index n3. A difference between the first refractive index n1 and the second refractive index n2 may be greater than or equal to about 0.45 and less than or equal to about 0.55. A difference between the second refractive index n2 and the third refractive index n3 may be greater than or equal to about 0.2 and less than or equal to about 0.42. A difference between the third refractive index n3 and the fourth refractive index n4 may be greater than or equal to about 0.1 and less than or equal to about 0.2. The difference between the first refractive index n1 and the second refractive index n2 may be greater than the difference between the second refractive index n2 and the third refractive index n3, and the difference between the second refractive index n2 and the third refractive index n3 may be greater than the difference between the third refractive index n3 and the fourth refractive index n4.

Referring to FIG. 4B, the composition of each layer may be analyzed using an X-ray photoelectron spectroscopy (hereinafter, referred to as an XPS) apparatus. The XPS is a spectroscopy method that analyzes elements by irradiating a sample with X-rays. When the sample is irradiated by the X-rays, photoelectrons are emitted, and it is possible to measure a binding energy, which is the energy required to emit the photoelectrons from the sample, by measuring a kinetic energy of photoelectrons. A qualitative analysis, a quantitative analysis, and a chemical bonding of elements may be analyzed by measuring the binding energy, which is an intrinsic property of atoms emitting photoelectrons.

The first inorganic insulating layer IIL1 the second inorganic insulating layer IIL2, and the third inorganic insulating layer IIL3 may include SiOₓN_{y}. An oxygen composition ratio x of the first inorganic insulating layer IIL1 may be 0.77, and a nitrogen composition ratio y of the first inorganic insulating layer IIL1 may be 0.42. In this case, the second refractive index n2 of the first inorganic insulating layer IIL1 may be about 1.57. An oxygen composition ratio x of the second inorganic insulating layer IIL2 may be 0.27, and a nitrogen composition ratio y of the second inorganic insulating layer IIL2 may be 0.65. In this case, the third refractive index n3 of the second inorganic insulating layer IIL2 may be about 1.77. An oxygen composition ratio x of the third inorganic insulating layer IIL3 may be 0.68, and a nitrogen composition ratio y of the third inorganic insulating layer IIL3 may be 0.47. In this case, the fourth refractive index n4 of the third inorganic insulating layer IIL3 may be about 1.62.

The composition ratio shown in FIG. 4B is not necessarily limited to the above. The composition ratio of each layer may be changed depending on the refractive index of each of the first inorganic insulating layer IIL1 the second inorganic insulating layer IIL2, and the third inorganic insulating layer IIL3.

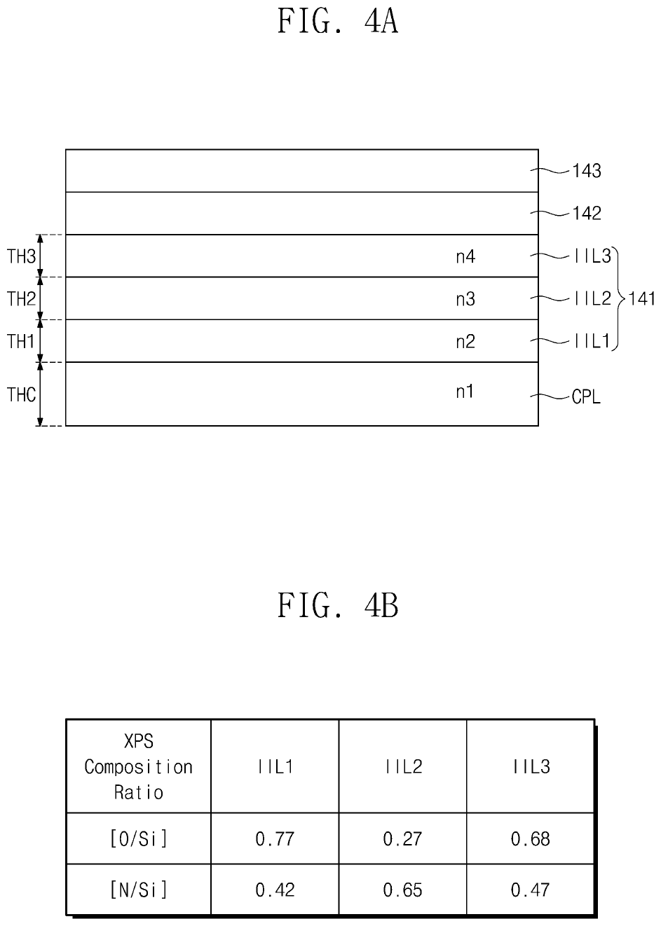

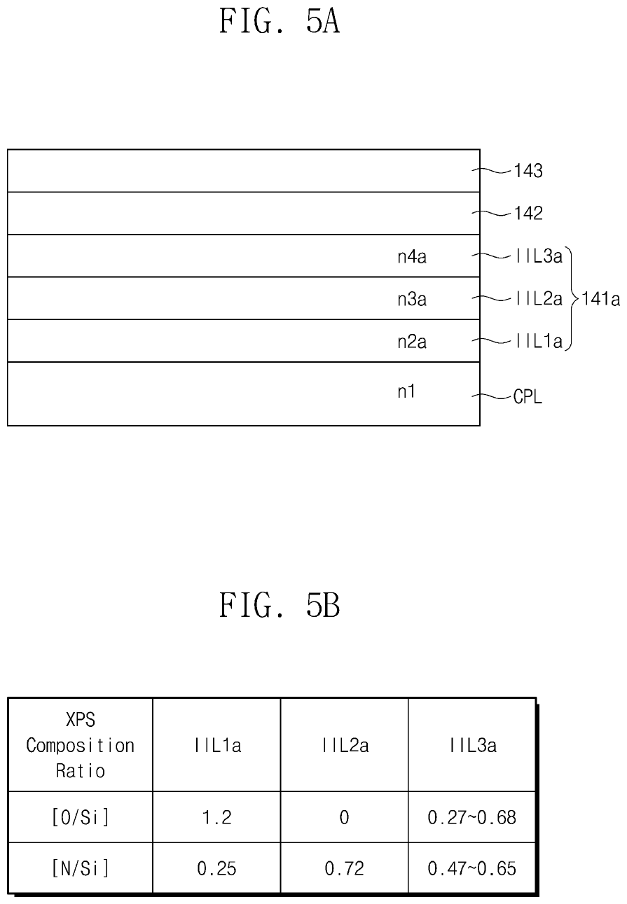

FIG. 5A is a cross-sectional view of some components of the display panel DP (refer to FIG. 1) according to an embodiment of the present disclosure. FIG. 5B is a table showing a composition ratio of an inorganic layer 141a of FIG. 5A. In FIGS. 5A and 5B, the same reference numerals may denote the same or similar elements in FIGS. 4A and 4B.

Referring to FIG. 5A, the inorganic layer 141a, which is adjacent to an organic capping layer CPL, between the inorganic layer 141a and an inorganic layer 143 of a thin film encapsulation layer 140a may include a plurality of inorganic insulating layers IIL1a, IIL2a, and IIL3a. The inorganic insulating layers IIL1a, IIL2a, and IIL3a may include a first inorganic insulating layer IIL1a, a second inorganic insulating layer IIL2a, and a third inorganic insulating layer IIL3a.

In FIG. 5A, the organic capping layer CPL may have a first refractive index n1 of about 2.0, and the first inorganic insulating layer IIL1a may have a second refractive index n2a of about 1.48. The second inorganic insulating layer IIL2a may have a third refractive index n3a of about 1.89, and the third inorganic insulating layer IIL3a may have a fourth refractive index n4a of about 1.70.

Referring to FIG. 5B, the first inorganic insulating layer IIL1a, the second inorganic insulating layer IIL2a, and the third inorganic insulating layer IIL3a may include SiOₓN_{y}. An oxygen composition ratio x of the first inorganic insulating layer IIL1a may be 1.2, and a nitrogen composition ratio y of the first inorganic insulating layer IIL1a may be 0.25. In this case, the second refractive index n2a of the first inorganic insulating layer IIL1a may be about 1.48. An oxygen composition ratio x of the second inorganic insulating layer IIL2a may be zero (0), and a nitrogen composition ratio y of the second inorganic insulating layer IIL2a may be 0.72. In this case, the third refractive index n3a of the second inorganic insulating layer IIL2a may be about 1.89. An oxygen composition ratio x of the third inorganic insulating layer IIL3a may be greater than 0.28 and smaller than 0.68, and a nitrogen composition ratio y of the third inorganic insulating layer IIL3a may be greater than 0.47 and smaller than 0.65. In this case, the fourth refractive index n4a of the third inorganic insulating layer IIL3a may be about 1.70.

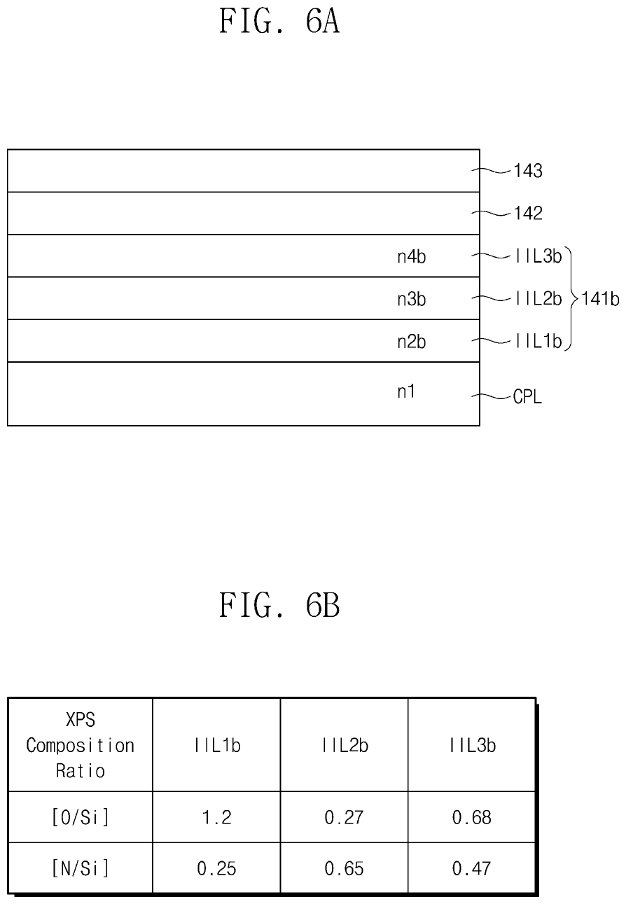

FIG. 6A is a cross-sectional view of some component of the display panel DP (refer to FIG. 1) according to an embodiment of the present disclosure. FIG. 6B is a table showing a composition ratio of an inorganic layer 141b of FIG. 6A. In FIGS. 6A and 6B, the same reference numerals may denote the same elements in FIGS. 4A and 4B.

Referring to FIG. 6A, the inorganic layer 141b, which is adjacent to an organic capping layer CPL, between the inorganic layer 141b and an inorganic layer 143 of a thin film encapsulation layer 140b may include a plurality of inorganic insulating layers IIL1b, IIL2b, and IIL3b. The inorganic insulating layers IIL1b, IIL2b, and IIL3b may include a first inorganic insulating layer IIL1b, a second inorganic insulating layer IIL2b, and a third inorganic insulating layer IIL3b.

In FIG. 6A, the organic capping layer CPL may have a first refractive index n1 of about 2.0, and the first inorganic insulating layer IIL1b may have a second refractive index n2b of about 1.48. The second inorganic insulating layer IIL2b may have a third refractive index n3b of about 1.77, and the third inorganic insulating layer IIL3b may have a fourth refractive index n4b of about 1.62.

Referring to FIG. 6B, the first inorganic insulating layer IIL1b, the second inorganic insulating layer IIL2b, and the third inorganic insulating layer IIL3b may include SiOₓN_{y}. An oxygen composition ratio x of the first inorganic insulating layer IIL1b may be 1.2, and a nitrogen composition ratio y of the first inorganic insulating layer IIL1b may be 0.25. In this case, the second refractive index n2 of the first inorganic insulating layer IIL1b may be about 1.48. An oxygen composition ratio x of the second inorganic insulating layer IIL2b may be 0.27, and a nitrogen composition ratio y of the second inorganic insulating layer IIL2b may be 0.65. In this case, the third refractive index n3 of the second inorganic insulating layer IIL2b may be about 1.77. An oxygen composition ratio x of the third inorganic insulating layer IIL3b may be 0.68, and a nitrogen composition ratio y of the third inorganic insulating layer IIL3b may be 0.47. In this case, the fourth refractive index n4 of the third inorganic insulating layer IIL3b may be about 1.62.

TABLE 1

| | | | Light | |
|---|---|---|---|---|
| | | | emission | Efficiency |
| conditions | | | efficiency | increase |
| POL | Comparative | organic capping layer (2.0, 640 Å) | 67.55 | 4.8% |
| structure | example 1 | first inorganic insulating layer | | |
| | | (1.77, 11000 Å) | | |
| | | second inorganic insulating layer | | |
| | | (1.62, 700 Å) | | |
| | Embodiment | organic capping layer (2.0, 600 Å) | 70.81 | |
| | example 1 | first inorganic insulating layer | | |
| | | (1.48, 1400 Å) | | |
| | | second inorganic insulating layer | | |
| | | (1.89, 9000 Å) | | |
| | | third inorganic insulating layer | | |
| | | (1.7, 650 Å) | | |
| OCF | Comparative | organic capping layer (2.0, 640 Å) | 95.51 | 8.8% |
| structure | example 2 | first inorganic insulating layer | | |
| | | (1.77, 11000 Å) | | |
| | | second inorganic insulating layer | | |
| | | (1.62, 700 Å) | | |
| | Embodiment | organic capping layer | 103.9 | |
| | example 2 | (2.0, 600 Å) | | |
| | | first inorganic insulating layer | | |
| | | (1.48, 1400 Å) | | |
| | | second inorganic insulating layer | | |
| | | (1.89, 9000 Å) | | |
| | | third inorganic insulating layer | | |
| | | (1.7, 650 Å) | | |

Referring to Table 1 and FIGS. 1 to 6B, display devices according to comparative example 1 and embodiment example 1 may include the optical member PF (refer to FIG. 3A). The optical member PF may be the polarizing film. Display devices according to comparative example 2 and embodiment example 2 may include the color filter 320 shown in FIGS. 2A and 2B. In Table 1, the display device according to comparative example 1 having a two-layer structure may include the polarizing film, and the inorganic layer 141 adjacent to the organic capping layer CPL may include two inorganic insulating layers. In comparative example 1, the organic capping layer may have the refractive index of about 2.0 and may have the thickness of about 640 angstroms (Å). In comparative example 1, the first inorganic insulating layer may have the refractive index of about 1.77 and may have the thickness of about 11000 angstroms (Å). In comparative example 1, the second inorganic insulating layer may have the refractive index of about 1.62 and may have the thickness of about 700 angstroms (Å).

In Table 1, the display device according to embodiment example 1 having a three-layer structure may include the polarizing film, and the inorganic layer 141a adjacent to the organic capping layer CPL may include three inorganic insulating layers IIL1a, IIL2a, and IIL3a. In embodiment example 1, the organic capping layer CPL may have the refractive index of about 2.0 and may have the thickness of about 600 angstroms (Å). In embodiment example 1, the first inorganic insulating layer IIL1a may have the refractive index of about 1.48 and may have the thickness of about 1400 angstroms (AA). In embodiment example 1, the second inorganic insulating layer IIL2a may have the refractive index of about 1.89 and may have the thickness of about 9000 angstroms (Å). In embodiment example 1, the third inorganic insulating layer IIL3a may have the refractive index of about 1.7 and may have the thickness of about 650 angstroms (Å).

In Table 1, the display device according to comparative example 2 having the two-layer structure may include the color filter 320, and the inorganic layer 141 adjacent to the organic capping layer CPL may include two inorganic insulating layers. In comparative example 2, the organic capping layer CPL may have the refractive index of about 2.0 and may have the thickness of about 640 angstroms (Å). In comparative example 2, the first inorganic insulating layer may have the refractive index of about 1.77 and may have the thickness of about 11000 angstroms (Å). In comparative example 2, the second inorganic insulating layer may have the refractive index of about 1.62 and may have the thickness of about 700 angstroms (Å).

In Table 1, the display device according to embodiment example 2 having the three-layer structure may include the color filter 320, and the inorganic layer 141a adjacent to the organic capping layer CPL may include three inorganic insulating layers IILa, IIL2a, and IIL3a. In embodiment example 2, the organic capping layer CPL may have the refractive index of about 2.0 and may have the thickness of about 600 angstroms (Å). In embodiment example 2, the first inorganic insulating layer IIL1a may have the refractive index of about 1.48 and may have the thickness of about 1400 angstroms (Å). In embodiment example 2, the second inorganic insulating layer IIL2a may have the refractive index of about 1.89 and may have the thickness of about 9000 angstroms (Å). In embodiment example 2, the third inorganic insulating layer IIL3a may have the refractive index of about 1.7 and may have the thickness of about 650 angstroms (Å).

When comparative example 1 is compared with embodiment example 1, a light emission efficiency of comparative example 1 is about 67.55, a light emission efficiency of embodiment example 1 is about 70.81, and the light emission efficiency of embodiment example 1 is higher than the light emission efficiency of comparative example 1. When comparative example 2 is compared with embodiment example 2, a light emission efficiency of comparative example 2 is about 95.51, a light emission efficiency of embodiment example 2 is about 103.9, and the light emission efficiency of embodiment example 2 is higher than the light emission efficiency of comparative example 2. In both the POL structure and the OCF structure, the light emission efficiency is higher when three inorganic insulating layers are included (embodiment example 1 and embodiment example 2) than when two inorganic insulating layers are included (comparative example 1 and comparative example 1).

When comparative example 1 is compared with comparative example 2, the light emission efficiency of comparative example 1 is about 67.55, the light emission efficiency of comparative example 2 is about 70.81, and the light emission efficiency of comparative example 2 is higher than the light emission efficiency of comparative example 1. When embodiment example 1 is compared with embodiment example 2, the light emission efficiency of embodiment example 1 is about 70.81, the light emission efficiency of embodiment example 2 is about 103.9, and the light emission efficiency of embodiment example 2 is higher than the light emission efficiency of embodiment example 1. The light emission efficiency in the case of the POL structure (comparative example 1 and embodiment example 1) may be higher than the light emission efficiency in the case of the OCF structure (comparative example 2 and embodiment example 2).

In addition, an increase of the light emission efficiency of the POL structure including two inorganic insulating layers (comparative example 1) and the POL structure including three inorganic insulating layers (embodiment example 1) is about 4.8%, and an increase of the light emission efficiency of the OCF structure including two inorganic insulating layers (comparative example 2) and the OCF structure including three inorganic insulating layers (embodiment example 2) is about 8.8%. As described above, it is observed that the structure including three inorganic insulating layers exhibits an efficiency increase effect higher when applied to the OCF structure (embodiment example 2) than when applied to the POL structure (embodiment example 1).

According to the above, the display device DD may include the organic capping layer CPL, the first inorganic insulating layer IIL1 the second inorganic insulating layer IIL2, and the third inorganic insulating layer IIL3, which are sequentially stacked on the light emitting element LD. The refractive index of the organic capping layer CPL and the refractive index of the second inorganic insulating layer IIL2 may be greater than the refractive index of the first inorganic insulating layer IIL1, and the refractive index of the first inorganic insulating layer IIL1 and the refractive index of the third inorganic insulating layer IIL3 may be smaller than the refractive index of the second inorganic insulating layer IIL2. In this case, a constructive interference may occur according to a difference in refractive index between the organic capping layer CPL, the first inorganic insulating layer IIL1 the second inorganic insulating layer IIL2, and the third inorganic insulating layer IIL3. When the display device DD includes the organic capping layer CPL, the first inorganic insulating layer IIL1 the second inorganic insulating layer IIL2, and the third inorganic insulating layer IIL3, which satisfy the refractive index conditions, a change in color according to a viewing angle of the display device may be reduced, and a light extraction efficiency of the display device may be increased.

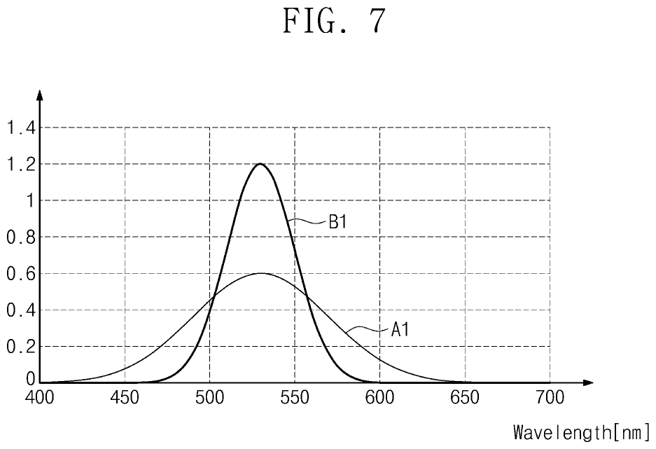

FIG. 7 is a graph showing spectral results of a green light passing through an inorganic layer according to a comparative example and an inorganic layer according to an embodiment of the present disclosure.

Referring to FIG. 7, a first spectrum A1 shows a spectrum of a display device including the inorganic layer 141 (refer to FIG. 4A) that includes only two inorganic insulating layers. As an example, the inorganic layer 141 corresponding to the first spectrum A1 may include only the second inorganic insulating layer IIL2 and the third inorganic insulating layer IIL3. A second spectrum B1 shows a spectrum of the display device DD (refer to FIG. 1) including the inorganic layer 141 that includes three inorganic insulating layers. As an example, the inorganic layer 141 corresponding to the second spectrum B1 may include the first inorganic insulating layer IIL1 the second inorganic insulating layer IIL2, and the third inorganic insulating layer IIL3.

The second spectrum B1 corresponding to the display device DD including three inorganic insulating layers may have substantially the same area as that of the first spectrum A1 corresponding to the display device including two inorganic insulating layers. The second spectrum B1 has a narrower width than that of the first spectrum A1 and has a larger maximum than that of the first spectrum A1 in the amount of light. This is because constructive and destructive interferences of light occur due to the refractive index between the three inorganic insulating layers IIL1 IIL2, and IIL3 and the intensity of light emitted from the front surface of the display panel DP (refer to FIG. 2a) increases. Accordingly, in the case of the display device including three inorganic insulating layers, a strong microcavity may be implemented in a green device. FIGS. 7 to 9b show a green light spectrum as a representative example, however, the same result may be obtained in a blue light spectrum. Accordingly, in the case of the display device including three inorganic insulating layers, a strong microcavity may be implemented in a blue device.

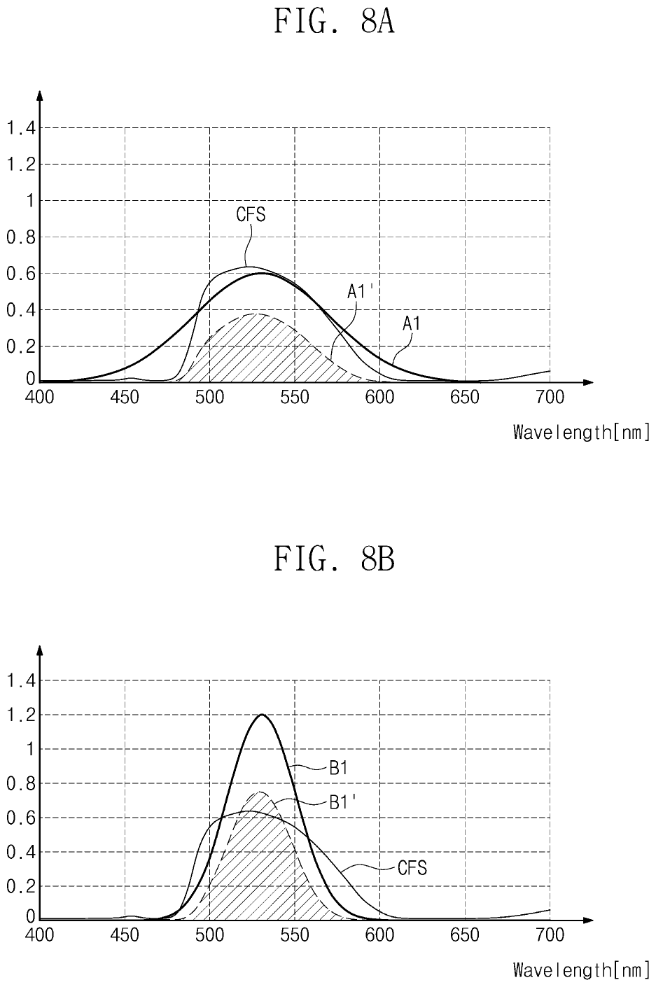

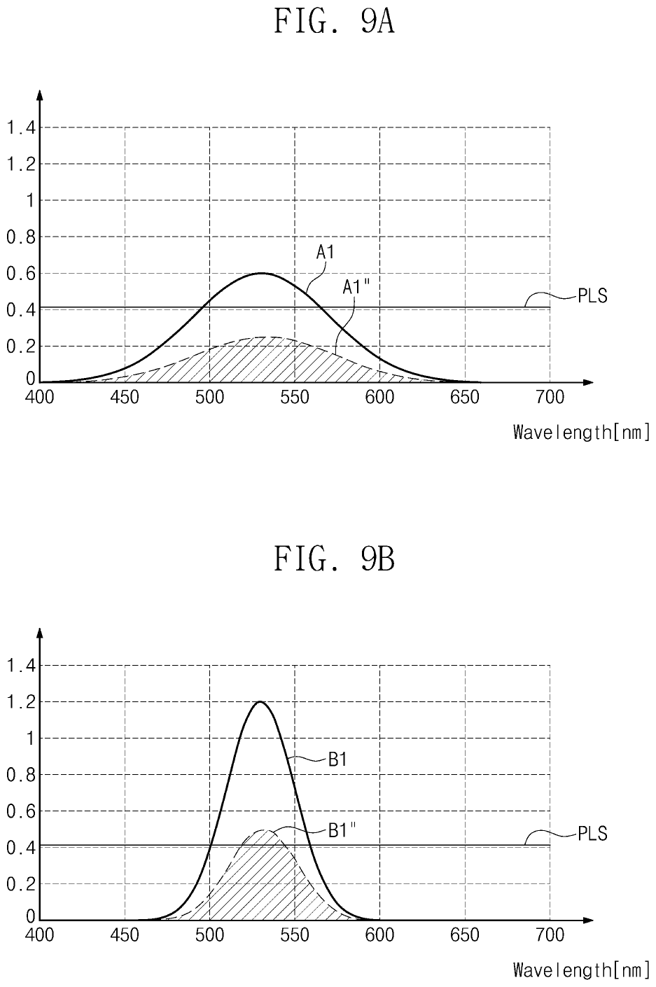

FIG. 8A is a graph showing spectral results of a green light before and after passing through a color filter of a display device including two inorganic insulating layers. FIG. 8B is a graph showing spectral results of a green light before and after passing through a color filter of a display device including three inorganic insulating layers according to an embodiment of the present disclosure. FIG. 9A is a graph showing spectral results of a green light before and after passing through a polarizing film of a display device including two inorganic insulating layers. FIG. 9B is a graph showing spectral results of a green light before and after passing through a polarizing film of a display device including three inorganic insulating layers according to an embodiment of the present disclosure.

Referring to FIG. 8A, a first spectrum A1 may be a green light spectrum before the green light passes through the color filter of the display device including two inorganic insulating layers. A first′ spectrum A1′ may be a green light spectrum after the green light passes through the color filter of the display device including two inorganic insulating layers. A color filter spectrum CFS shows a wavelength range and an intensity corresponding to a transmissive area of the color filter. For example, the first spectrum A1 may be changed to the first′ spectrum A1′ after the green light passes through the color filter. As an example, the first spectrum A1 may be changed to the first′ spectrum A1′ having a narrower width than that of the first spectrum A1 and a smaller maximum value in the amount of the light than that of the first spectrum A1 after the green light passes through the color filter.

Referring to FIG. 8B, a second spectrum B1 may be a green light spectrum before the green light passes through the color filter of the display device including three inorganic insulating layers. A second′ spectrum B1′ may be a green light spectrum after the green light passes through the color filter of the display device including three inorganic insulating layers. The second spectrum B1 may be changed to the second′ spectrum B1′ after the green light passes through the color filter. As an example, the second spectrum B1 may be changed to the second′ spectrum B1′ having a narrower width than that of the second spectrum B1 and a maximum value in the amount of the light approaching a maximum value of the color filter spectrum after the green light passes through the color filter.

Referring to FIGS. 8A and 8B, the second′ spectrum B1′ may have an area greater than that of the first′ spectrum A1′. In the case of the second spectrum B1 corresponding to the display device including three inorganic insulating layers, the constructive and destructive interferences of the light may occur due to the refractive index between the three inorganic insulating layers IIL1 IIL2, and IIL3. Thus, a wavelength width may be reduced, and the intensity of the light emitted from the front surface of the display panel DP (refer to FIG. 2a) may increase. The color filter spectrum CFS may overlap a wavelength band of the second spectrum B1 and may transmit more light.

Referring to FIG. 9A, a first″ spectrum A1″ may be a green light spectrum after the green light passes through the polarizing film of the display device including two inorganic insulating layers. A spectrum of the polarizing film PLS does not have different transmittances for each wavelength band and may have a constant transmittance. For example, the first spectrum A1 may be changed to the first″ spectrum A1″ after through the polarizing film, and the first″ spectrum A1″ may be partially transmitted in the entire wavelength band. Referring to FIG. 9B, a second″ spectrum B1″ may be a green light spectrum after the green light passes through the polarizing film of the display device including three inorganic insulating layers. Since the spectrum PLS of the polarizing film may have a constant transmittance in the entire wavelength, the second spectrum B1 may be changed to the second″ spectrum B1″ after through the polarizing film, and the second″ spectrum B1″ may be partially transmitted in the entire wavelength band. Referring to FIGS. 7 to 9B, the second′ spectrum B1′ may have an area greater than that of the second″ spectrum B1″. The second″ spectrum B1″ may show a light emission spectrum of the display device including the three inorganic insulating layers and the polarizing film, and the second′ spectrum B1′ may show the light emission spectrum of the display device including the three inorganic insulating layers and the color filter.

The polarizing film has the constant transmittance at all wavelengths, and the color filter spectrum CFS has a high transmittance at specific wavelengths. As an example, the spectrum of the color filter may have the high transmittance in a wavelength range from about 450 nm to about 600 nm. In the case where the light passes through the color filter, the light efficiency may decrease by about the transmittance of the color filter, and when the light passes through the polarizing film, the light efficiency may decrease by about the transmittance of the polarizing film.

The second spectrum B1 of the display device including the three inorganic insulating layers may have a transmittance higher at the specific wavelength range than that of the first spectrum A1. As an example, the second spectrum B1 has the high transmittance in the wavelength range from about 450 nm to about 600 nm. When the second′ spectrum B1′ obtained after the green light passes through the color filter is compared with the second″ spectrum B1″ obtained after the green light passes through the polarizing film, a ratio of decrease in the efficiency of the green device and the blue device is smaller in the second′ spectrum B1′ than in the second″ spectrum B1″, and thus, an overall light emission efficiency of the second′ spectrum B1′ may be higher than that of the second″ spectrum B1″. This is because more light is absorbed in the specific wavelength range of the color filter spectrum CFS and the specific wavelength range overlaps the second spectrum B1. FIGS. 8B and 9B show the specific wavelength range of the green color as a representative example, however, the specific wavelength range may correspond to the blue color. For example, the device spectrum may be changed while passing through the color filter. Accordingly, the transmittance of the color filter may be higher than the transmittance of the polarizing film having the constant transmittance in all wavelengths, and thus, the second′ spectrum B1′ may have the area greater than that of the second″ spectrum B1″.

Although the embodiments of the present disclosure have been described, it is understood that the present disclosure is not necessarily limited to these embodiments but various changes and modifications can be made by one ordinary skilled in the art within the spirit and scope of the present disclosure as hereinafter claimed.

What is claimed is:

1. A display device, comprising:
a display panel comprising a light emitting element, an organic capping layer disposed on the light emitting element and having a first refractive index, and a thin film encapsulation layer disposed on the organic capping layer; and
a color filter disposed on the display panel and corresponding to the light emitting element,
wherein the thin film encapsulation layer comprises:
a first inorganic insulating layer disposed directly on the organic capping layer, the first inorganic insulating layer having a second refractive index;
a second inorganic insulating layer disposed directly on the first inorganic insulating layer, the second inorganic insulating layer having a third refractive index;
a third inorganic insulating layer disposed directly on the second inorganic insulating layer, the third inorganic insulating layer having a fourth refractive index;
an organic layer disposed directly on the third inorganic insulating layer; and
a fourth inorganic insulating layer disposed directly on the organic layer,
wherein the first refractive index and the third refractive index are each greater than the second refractive index, and
wherein the second refractive index and the fourth refractive index are each smaller than the third refractive index.

2. The display device of claim 1, wherein a difference between the first refractive index and the second refractive index is greater than a difference between the second refractive index and the third refractive index, and
wherein a difference between the second refractive index and the third refractive index is greater than a difference between the third refractive index and the fourth refractive index.

3. The display device of claim 1, wherein the organic capping layer has a thickness that is greater than or equal to about 450 angstroms and less than or equal to about 650 angstroms, and
wherein the first refractive index is greater than or equal to about 1.8 and less than or equal to about 2.1.

4. The display device of claim 1, wherein the first inorganic insulating layer has a thickness that is greater than or equal to about 1100 angstroms and less than or equal to about 1600 angstroms, and
wherein the second refractive index is greater than or equal to about 1.4 and less than or equal to about 1.7.

5. The display device of claim 1, wherein the second inorganic insulating layer has a thickness that is greater than or equal to about 8000 angstroms and less than or equal to about 11000 angstroms, and
wherein the third refractive index is greater than or equal to about 1.75 and less than or equal to about 1.9.

6. The display device of claim 1, wherein the third inorganic insulating layer has a thickness that is greater than or equal to about 500 angstroms and less than or equal to about 800 angstroms, and
wherein the fourth refractive index is greater than or equal to about 1.6 and less than or equal to about 1.7.

7. The display device of claim 1, wherein the first inorganic insulating layer, the second inorganic insulating layer, and the third inorganic insulating layer each comprise SiOxNy,
wherein the first inorganic insulating layer has an oxygen composition ratio (x) of about 0.77 and a nitrogen composition ratio (y) of about 0.42,
wherein the second inorganic insulating layer has an oxygen composition ratio (x) of about 0.27 and a nitrogen composition ratio (y) of about 0.65, and
wherein the third inorganic insulating layer has an oxygen composition ratio (x) of about 0.68 and a nitrogen composition ratio (y) of about 0.47.

8. The display device of claim 1, wherein the first inorganic insulating layer, the second inorganic insulating layer, and the third inorganic insulating layer each comprise SiOxNy,
wherein the first inorganic insulating layer has an oxygen composition ratio (x) of about 1.2 and a nitrogen composition ratio (y) of about 0.25,
wherein the second inorganic insulating layer has an oxygen composition ratio (x) of about 0 and a nitrogen composition ratio (y) of about 0.72, and
wherein the third inorganic insulating layer has an oxygen composition ratio (x) that is greater than about 0.27 and smaller than about 0.68 and a nitrogen composition ratio (y) that is greater than about 0.47 and smaller than about 0.65.

9. The display device of claim 1, wherein the first inorganic insulating layer, the second inorganic insulating layer, and the third inorganic insulating layer each comprise SiOxNy,
wherein the first inorganic insulating layer has an oxygen composition ratio (x) of about 1.2 and a nitrogen composition ratio (y) of about 0.25,
wherein the second inorganic insulating layer has an oxygen composition ratio (x) of about 0.27 and a nitrogen composition ratio (y) of about 0.65, and
wherein the third inorganic insulating layer has an oxygen composition ratio (x) of about 0.68 and a nitrogen composition ratio (y) of about 0.47.

10. The display device of claim 1, wherein the first inorganic insulating layer, the second inorganic insulating layer, and the third inorganic insulating layer each comprise SiOxNy,
wherein an oxygen composition ratio (x) is greater than or equal to about 0 and less than or equal to about 1.2, and
wherein a nitrogen composition ratio (y) is greater or equal to about 0.25 and less than or equal to about 0.72.

11. The display device of claim 1, further comprising:
a black matrix disposed adjacent to the color filter; and
an overcoat layer covering the color filter and the black matrix.

12. The display device of claim 1, further comprising an input sensor layer disposed between the thin film encapsulation layer and the color filter.

13. A display device, comprising:
a display panel comprising a light emitting element, an organic capping layer disposed on the light emitting element and having a first refractive index, and a thin film encapsulation layer disposed on the organic capping layer;
an input sensor layer disposed directly on the display panel; and
an optical layer disposed on the input sensor layer, the thin film encapsulation layer comprising:
a first inorganic insulating layer disposed directly on the organic capping layer, the first inorganic insulating layer having a second refractive index;
a second inorganic insulating layer disposed directly on the first inorganic insulating layer, the second inorganic insulating layer having a third refractive index;
a third inorganic insulating layer disposed directly on the second inorganic insulating layer, the third inorganic insulating layer having a fourth refractive index;
an organic layer disposed directly on the third inorganic insulating layer; and
a fourth inorganic insulating layer disposed directly on the organic layer,
wherein the first refractive index and the third refractive index are each greater than the second refractive index,
wherein the second refractive index and the fourth refractive index are each smaller than the third refractive index,
wherein a difference between the first refractive index and the second refractive index is greater than a difference between the second refractive index and the third refractive index, and
wherein the difference between the second refractive index and the third refractive index is greater than a difference between the third refractive index and the fourth refractive index.

14. The display device of claim 13, wherein the difference between the first refractive index and the second refractive index is greater than or equal to about 0.45 and less than or equal to about 0.55,
wherein the difference between the second refractive index and the third refractive index is greater than or equal to about 0.2 and less than or equal to about 0.42, and
wherein the difference between the third refractive index and the fourth refractive index is greater than or equal to about 0.1 and less than or equal to about 0.2.

15. The display device of claim 13, wherein the optical layer comprises a polarizing film and/or a color filter.

16. The display device of claim 13, wherein the input sensor layer comprises:
a base insulating layer disposed on the display panel;
a first conductive layer disposed on the base insulating layer;
a sensing insulating layer disposed on the first conductive layer;
a second conductive layer disposed on the sensing insulating layer; and
a cover layer disposed on the second conductive layer.

17. The display device of claim 13, wherein the organic capping layer has a thickness that is greater than or equal to about 450 angstroms and less than or equal to about 650 angstroms, and
wherein the first refractive index is greater than or equal to about 1.8 and less than or equal to about 2.1.

18. The display device of claim 13, wherein the first inorganic insulating layer has a thickness that is greater than or equal to about 1100 angstroms and less than or equal to about 1600 angstroms, and
wherein the second refractive index is greater than or equal to about 1.4 and less than or equal to about 1.7.

19. The display device of claim 13, wherein the second inorganic insulating layer has a thickness that is greater than or equal to about 8000 angstroms and less than or equal to about 11000 angstroms, and
wherein the third refractive index is greater than or equal to about 1.75 and less than or equal to about 1.9.

20. The display device of claim 13, wherein the third inorganic insulating layer has a thickness that is greater than or equal to about 500 angstroms and less than or equal to about 800 angstroms, and
wherein the fourth refractive index is greater than or equal to about 1.6 and less than or equal to about 1.7.
